(19) United States
(12) Patent Application Publication
(10) Pub. No.: US 2011/0088760 A1
(43) Pub. Date: Apr. 21, 2011

(54) METHODS OF FORMING AN AMORPHOUS SILICON LAYER FOR THIN FILM SOLAR CELL APPLICATION

(75) Inventors: Shuran Sheng, Cupertino, CA (US); Yong-Kee Chae, Pleasanton, CA (US)

(73) Assignee: APPLIED MATERIALS, INC., Santa Clara, CA (US)

(21) Appl. No.: 12/582,323

(22) Filed: Oct. 20, 2009

(51) Int. Cl. H01L 31/00; H01L 31/18

(52) U.S. Cl. 136/255; 438/96; 257/E31.003; 257/E31.032

(57) ABSTRACT

A photovoltaic device and methods for forming an amorphous silicon layer for use in a photovoltaic device are provided. In one embodiment, a photovoltaic device includes a p-type amorphous silicon layer formed on a substrate, a barrier layer formed on the p-type amorphous silicon layer, and an intrinsic type amorphous silicon layer formed on the barrier layer. The barrier layer is a carbon doped amorphous silicon layer.

### BACKGROUND OF THE INVENTION

1. Field of the Invention

Embodiments of the present invention generally relate to solar cells and methods for forming the same. More particularly, embodiments of the present invention relate to forming an amorphous silicon layer used in thin-film and/or crystalline solar cells.

2. Description of the Related Art

Crystalline silicon solar cells and thin film solar cells are two types of solar cells. Crystalline silicon solar cells typically use either mono-crystalline substrates (i.e., single-crystal substrates of pure silicon) or multi-crystalline silicon substrates (i.e., poly-crystalline or polysilicon). Additional film layers are deposited onto the silicon substrates to improve light capture, form the electrical circuits, and protect the devices. Thin-film solar cells use thin layers of materials deposited on suitable substrates to form one or more p-n junctions. Suitable substrates include glass, metal, and polymer substrates.

Different types of silicon based layers, such as amorphous silicon layer, microcrystalline silicon layer, nanocrystalline silicon layer or polycrystalline silicon layer, may be used to form thin-film solar cell junctions. Generally, different degree of crystallinity of the silicon based layer will influence its light-absorbing characteristics. An intrinsic type amorphous silicon layer often absorbs light at different wavelengths from an intrinsic type crystalline silicon layer. Furthermore, the intrinsic type amorphous silicon layer formed in the solar cell junction often generate less current as compared with the intrinsic type crystalline silicon layer that has higher degree of crystallinity in the solar cell junction.

In a conventional single junction solar cell structure, an intrinsic type amorphous silicon layer is often used as the photoelectric conversion layer to convert light into current. The optical and electrical properties of the amorphous silicon layer used in the thin-film solar cell devices often significantly influence the conversion efficiency and electrical performance of the solar cell devices. In a stacked tandem junction solar cell, an intrinsic type amorphous silicon top cell is often stacked on an intrinsic type crystalline silicon bottom cell in order to absorb light at different wavelengths and spectrum so as to obtain the broadest possible absorption characteristics. In this configuration, as different intrinsic type silicon materials are used in the top and bottom cells respectively, current generation mismatch is often found in between the cells, thereby resulting in unstable solar cell device structure. Unstable solar cell device structure may result in high likelihood of device failure. Accordingly, there is a need in the field to form an intrinsic type amorphous silicon junction cell that may generate current matched with or close to the current generated from the intrinsic type crystalline silicon junction cell.

Therefore, there is a need for an improved method for forming an amorphous silicon layer used for solar cell junctions.

### SUMMARY OF THE INVENTION

Embodiments of the invention provide a photovoltaic device and methods for forming an amorphous silicon layer for use in a photovoltaic device. In one embodiment, a photovoltaic device includes a p-type amorphous silicon layer formed on a substrate, a barrier layer formed on the p-type amorphous silicon layer, wherein the barrier layer is a carbon doped amorphous silicon layer, and an intrinsic type amorphous silicon layer formed on the barrier layer.

In another embodiment, a method of forming a solar cell device includes forming a p-type amorphous silicon layer on a surface of a substrate, forming a barrier layer on the p-type amorphous silicon layer, wherein the barrier layer is a carbon doped amorphous silicon layer, and forming an intrinsic type amorphous silicon layer on the barrier layer.

In yet another embodiment, a method of forming a solar cell device includes supplying a first gas mixture in a processing chamber to form a p-type amorphous silicon layer on a surface of a substrate, supplying a second gas mixture in the processing chamber to form a barrier layer on the p-type amorphous silicon layer, wherein the barrier layer is a carbon doped amorphous silicon layer and the second gas mixture supplied to form the barrier layer includes at least a carbon containing gas and a silicon containing gas, and forming an intrinsic type amorphous silicon layer on the barrier layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a schematic side-view of a single junction thin-film solar cell according to one embodiment of the invention;

FIG. 2 is a schematic side-view of a tandem junction thin-film solar cell according to one embodiment of the invention;

FIG. 3 is a process flow diagram for forming a portion of an amorphous based thin-film solar cell according to one embodiment of the invention;

FIG. 4 is a cross-sectional view of an apparatus according to one embodiment of the invention;

FIG. 5 is a plan view of an apparatus according to another embodiment of the invention; and

FIG. 6 is a plan view of a portion of a production line having apparatuses of FIGS. 4 and 5 incorporated therein according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Thin-film solar cells are generally formed from numerous types of films, or layers, put together in many different ways. Most films used in such devices incorporate a semiconductor element, which may comprise silicon, germanium, carbon, boron, phosphorous, nitrogen, oxygen, hydrogen and the like. Characteristics of the different films include degrees of crystallinity, dopant type, dopant concentration, film refractive index, film extinction coefficient, film transparency, film absorption, and conductivity. Typically, most of these films can be formed by use of a chemical vapor deposition process, which may include some degree of ionization or plasma formation.

The present invention provides methods for depositing an intrinsic amorphous silicon based solar layer in a cell junction with low film optical bandgap and broad wavelength absorption range. In one embodiment, the intrinsic amorphous silicon layer utilized in the solar cell junction may be formed under a process condition having a relatively high temperature, a relatively low process pressure and a relatively low hydrogen dilution (e.g., low H₂/SiH₄ flow ratio). Furthermore, a barrier layer may be additionally formed prior to the deposition of the intrinsic amorphous silicon layer in the junction cell to increase overall device current conversion efficiency.

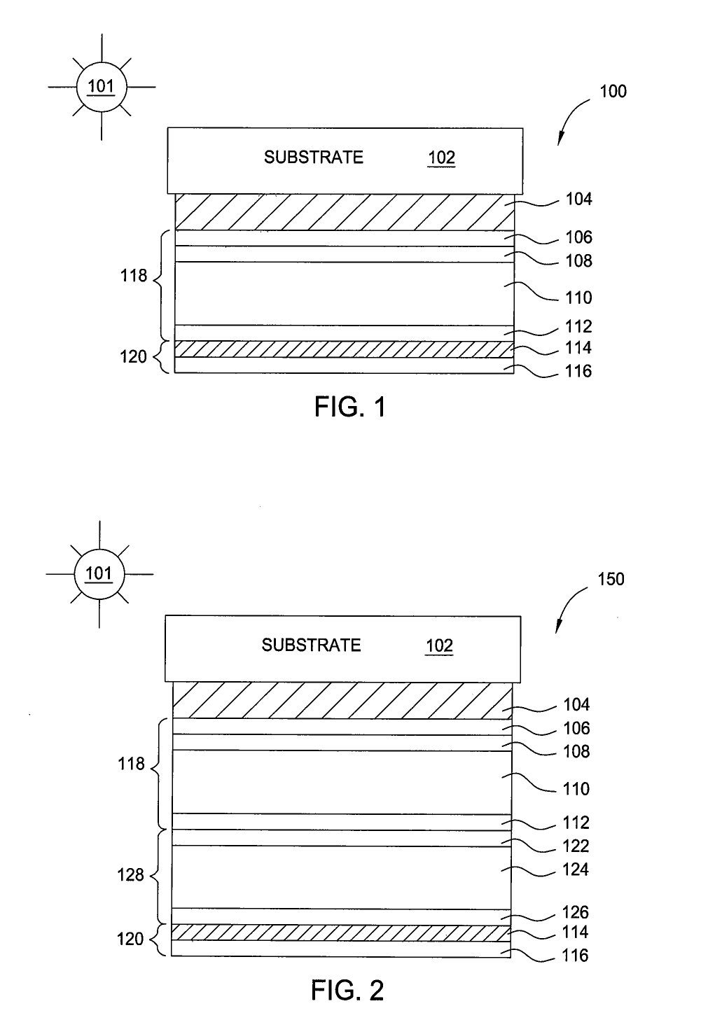

FIG. 1 is a schematic diagram of an embodiment of a single junction solar cell 100 oriented toward the light or solar radiation 101. Solar cell 100 comprises a substrate 102, such as a glass substrate, polymer substrate, metal substrate, or other suitable substrate, with thin films formed thereover. The solar cell 100 further comprises a first transparent conductive oxide (TCO) layer 104 formed over the substrate 102, a first p-i-n junction 118 formed over the first TCO layer 104. After the first p-i-n junction 118 is formed on the substrate 102, a metal back reflector 120 may be formed over the first p-i-n junction 118. The metal back reflector 120 includes a second TCO layer 114 and a metal back layer 116 formed over the second TCO layer 114.

To improve light absorption by enhancing light trapping, the substrate and/or one or more of thin films formed thereover may be optionally textured (not shown) by wet, plasma, ion, and/or mechanical processes as needed. The first TCO layer 104 and the second TCO layer 114 may each comprise tin oxide, zinc oxide, indium tin oxide, cadmium stannate, combinations thereof, or other suitable materials. It is understood that the TCO materials may also include additional dopants and components. For example, zinc oxide may further include dopants, such as aluminum, gallium, boron, and other suitable dopants. In one embodiment, zinc oxide may comprise about 5 atomic % or less of dopants, for example about 2.5 atomic % or less aluminum. In certain instances, the substrate 102 may be provided by the glass manufacturers with the first TCO layer 104 already provided.

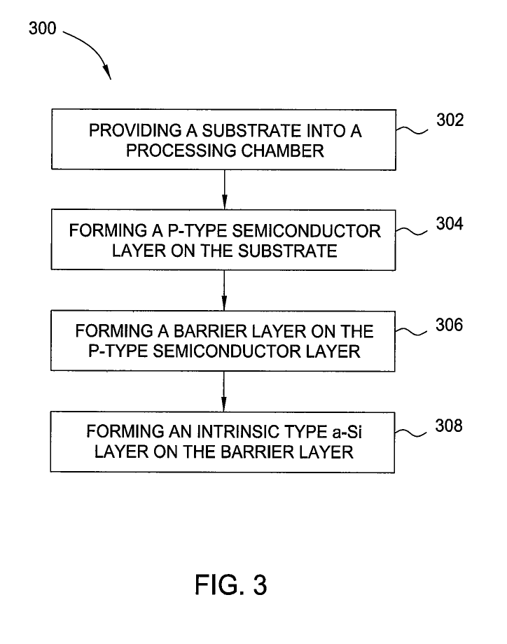

The first p-i-n junction 118 may comprise a p-type semiconductor layer 106, an intrinsic type semiconductor layer 110 formed over the p-type semiconductor layer 106, and an n-type semiconductor layer 112 formed over the intrinsic type semiconductor layer 110. A barrier layer 108 may be disposed between the p-type semiconductor layer 106 and the intrinsic type semiconductor layer 110 as needed to suppress the diffusion of impurities or dopants. The p-type, intrinsic type, n-type semiconductor layers 106, 110, 112 and the barrier layer 108 may be manufactured by silicon based materials or doped silicon based materials, such as amorphous based silicon layer, microcrystalline silicon based layer, nanocrystalline silicon based layer, or polysilicon based layer. In one embodiment, the p-type semiconductor layer 106 is a p-type amorphous silicon layer. The intrinsic type semiconductor layer 110 is an intrinsic type amorphous silicon layer. The n-type semiconductor layer 112 is an n-type microcrystalline silicon layer. The barrier layer 108 is a doped intrinsic type amorphous silicon layer, such as a carbon doped intrinsic type amorphous silicon layer. Details regarding the structures, film properties and manufacture method of the intrinsic type amorphous silicon layer 110 and the barrier layer 108 will be further discussed below with referenced to FIG. 3.

In certain embodiments, the p-type amorphous silicon layer 106 may be formed to a thickness between about 60 Å and about 300 Å. In certain embodiments, the barrier layer 108 may be formed to a thickness between about 0 Å and about 200 Å, such as about less than 100 Å. In certain embodiments, the intrinsic type amorphous silicon layer 110 may be formed to a thickness between about 1,500 Å and about 3,500 Å. In certain embodiments, the n-type microcrystalline semiconductor layer 112 may be formed to a thickness between about 100 Å and about 400 Å.

In another exemplary embodiment depicted in FIG. 2, a tandem and/or multiple junction solar cell 150 may be formed on the substrate 102 to enhance current generation and increase conversion efficiency. In addition to the first p-i-n junction 118 formed on the substrate 102, a second p-i-n junction 128 may be formed between the first p-i-n junction 118 and the second TCO layer 114 to increase current generation and retain light in the junction cells for a longer time. Similarly, the second p-i-n junction 128 also includes a p-type semiconductor layer 122, an intrinsic type semiconductor layer 124 and a n-type semiconductor layer 126. The p-type, intrinsic type and n-type semiconductor layer 122, 124, 126 may be manufactured by silicon based materials or doped silicon based materials, such as amorphous based silicon layer, microcrystalline silicon based layer, nanocrystalline silicon based layer, or polysilicon based layer. In one embodiment, the p-type semiconductor layer 122 is a p-type microcrystalline silicon layer. The intrinsic type semiconductor layer 124 is an intrinsic type microcrystalline silicon layer. The n-type semiconductor layer 126 is a n-type amorphous silicon layer.

In certain embodiments, the p-type microcrystalline silicon layer 122 may be formed to a thickness between about 100 Å and about 500 Å. In certain embodiments, the intrinsic type microcrystalline silicon layer 124 may be formed to a thickness between about 10,000 Å and about 30,000 Å. In certain embodiments, the n-type amorphous silicon layer 126 may be formed to a thickness between about 100 Å and about 600 Å.

The metal back layer 116 may include, but not limited to a material selected from the group consisting of Al, Ag, Ti, Cr, Au, Cu, Pt, alloys thereof, or combinations thereof. Other processes may be performed to form the solar cell 100, such a laser scribing processes. Other films, materials, substrates, and/or packaging may be provided over metal back layer 116 to complete the solar cell device. The formed solar cells may be interconnected to form modules, which in turn can be connected to form arrays.

Solar radiation 101 is primarily absorbed by the intrinsic layers 110, 124 of the p-i-n junctions 118, 128 and is converted to electron-holes pairs. The electric field created between the p-type layer 106, 122 and the n-type layer 112, 126 that stretches across the intrinsic layer 110, 124 causes electrons to flow toward the n-type layers 112, 126 and holes to flow toward the p-type layers 106, 122 creating a current. Generally, the first p-i-n junction 118 comprises an intrinsic type amorphous silicon layer 110 and the second p-i-n junction 128 comprises an intrinsic type microcrystalline silicon layer 124 since amorphous silicon and microcrystalline silicon absorb different wavelengths of the solar radiation 101. Therefore, the formed solar cell 100, 150 is more efficient, since it captures a larger portion of the solar radiation spectrum. The intrinsic layer 110, 124 of amorphous silicon and the intrinsic layer of microcrystalline are stacked in such a way that solar radiation 101 first strikes the intrinsic type amorphous silicon layer 110 and then strikes the intrinsic type microcrystalline silicon layer 124 since amorphous silicon has a larger bandgap than microcrystalline silicon. Solar radiation not absorbed by the first p-i-n junction 118 continues on to the second p-i-n junction 128.

Detail configurations and manufacture methods of the intrinsic amorphous silicon layer 110 and the barrier layer 108 will be discussed below with referenced to FIG. 3. For other film layers formed in the junctions cells, 118, 128, the intrinsic type microcrystalline silicon layer 124 may be deposited by providing a gas mixture of silane gas and hydrogen gas in a ratio of hydrogen to silane between about 20:1 and about 200:1. Silane gas may be provided at a flow rate between about 0.5 sccm/L and about 5 sccm/L. Hydrogen gas may be provided at a flow rate between about 40 sccm/L and about 400 sccm/L. In certain embodiments, the silane flow rate may be ramped up from a first flow rate to a second flow rate during deposition. In certain embodiments, the hydrogen flow rate may be ramped down from a first flow rate to a second flow rate during deposition. Applying RF power between about 300 mW/cm² or greater, preferably 600 mW/cm² or greater, at a chamber pressure between about 1 Torr and about 100 Torr, preferably between about 3 Torr and about 20 Torr, more preferably between about 4 Torr and about 12 Torr, such as about 1 Torr and 2 Torr, will generally deposit an intrinsic type microcrystalline silicon layer having crystalline fraction between about 20 percent and about 80 percent, preferably between 55 percent and about 75 percent, at a rate of about 200 Å/min or more, such as about 500 Å/min. In some embodiments, it may be advantageous to ramp the power density of the applied RF power from a first power density to a second power density during deposition. Furthermore, during deposition, the RF power density may be ramped down from a first range to a second range to prevent excess evolution of microcrystalline silicon structure along the orientation of the grain structures.

Charge collection is generally provided by doped semiconductor layers, such as silicon layers doped with p-type or n-type dopants. P-type dopants are generally Group III elements, such as boron or aluminum. N-type dopants are generally Group V elements, such as phosphorus, arsenic, or antimony. In most embodiments, boron is used as the p-type dopant and phosphorus as the n-type dopant. These dopants may be added to the p-type and n-type layers 106, 122, 112, 126 described above by including boron-containing or phosphorus-containing compounds in the reaction mixture. Suitable boron and phosphorus compounds generally comprise substituted and unsubstituted lower borane and phosphine oligomers. Some suitable boron compounds include trimethylboron (B(CH₃)₃ or TMB), diborane (B₂H₆), boron trifluoride (BF₃), and triethylboron (B(C₂H₅)₃ or TEB). Phosphine is the most common phosphorus compound. The dopants are generally provided with carrier gases, such as hydrogen, helium, argon, and other suitable gases. If hydrogen is used as the carrier gas, the total hydrogen in the reaction mixture comprises both hydrogen gas and hydrogen provided in the carrier gas. Thus hydrogen ratios will include the hydrogen used as a carrier gas for dopants.

Dopants will generally be provided as dilute gas mixtures in an inert gas. For example, dopants may be provided at molar or volume concentrations of about 0.5% in a carrier gas. If a dopant is provided at a volume concentration of 0.5% in a carrier gas flowing at 1.0 sccm/L, the resultant dopant flow rate will be 0.005 sccm/L. Dopants may be provided to a reaction chamber at flow rates between about 0.0002 sccm/L and about 0.1 sccm/L depending on the degree of doping desired. In general, dopant concentration is maintained between about 10¹⁸ atoms/cm² and about 10²⁰ atoms/cm².

In one embodiment, the p-type microcrystalline silicon layer 122 may be deposited by providing a gas mixture of hydrogen gas and silane gas in ratio of hydrogen-to-silane of about 200:1 or greater, such as 1000:1 or less, for example between about 250:1 and about 800:1, and in a further example about 601:1 or about 401:1. Silane gas may be provided at a flow rate between about 0.1 sccm/L and about 0.8 sccm/L, such as between about 0.2 sccm/L and about 0.38 sccm/L. Hydrogen gas may be provided at a flow rate between about 60 sccm/L and about 500 sccm/L, such as about 143 sccm/L. TMB may be provided at a flow rate between about 0.0002 sccm/L and about 0.0016 sccm/L, such as about 0.00115 sccm/L. If TMB is provided in a 0.5% molar or volume concentration in a carrier gas, then the dopant/carrier gas mixture may be provided at a flow rate between about 0.04 sccm/L and about 0.32 sccm/L, such as about 0.23 sccm/L. Applying RF power between about 50 mW/cm² and about 700 mW/cm², such as between about 290 mW/cm² and about 440 mW/cm², at a chamber pressure between about 1 Torr and about 100 Torr, such as between about 3 Torr and about 20 Torr, more preferably between 4 Torr and about 12 Torr, such as about 7 Torr or about 9 Torr, will deposit a p-type microcrystalline layer having crystalline fraction between about 20 percent and about 80 percent, such as between 50 percent and about 70 percent for a microcrystalline layer, at about 10 Å/min or more, such as about 143 Å/min or more.

In one embodiment, the n-type microcrystalline silicon layer 112 may be deposited by providing a gas mixture of hydrogen gas to silane gas in a ratio of about 100:1 or more, such as about 500:1 or less, such as between about 150:1 and about 400:1, for example about 304:1 or about 203:1. Silane gas may be provided at a flow rate between about 0.1 sccm/L and about 0.8 sccm/L, such as between about 0.32 sccm/L and about 0.45 sccm/L, for example about 0.35 sccm/L. Hydrogen gas may be provided at a flow rate between about 30 sccm/L and about 250 sccm/L, such as between about 68 sccm/L and about 143 sccm/L, for example about 71.43 sccm/L. Phosphine may be provided at a flow rate between about 0.0005 sccm/L and about 0.006 sccm/L, such as between about 0.0025 sccm/L and about 0.015 sccm/L, for example about 0.005 sccm/L. In other words, if phosphine is provided in a 0.5% molar or volume concentration in a carrier gas, then the dopant/carrier gas may be provided at a flow rate between about 0.1 sccm/L and about 5 sccm/L, such as between about 0.5 sccm/L and about 3 sccm/L, for example between about 0.9 sccm/L and about 1.088 sccm/L. Applying RF power between about 100 mW/cm² and about 900 mW/cm², such as about 370 mW/cm², at a chamber pressure of between about 1 Torr and about 100 Torr, for example between about 3 Torr and about 20 Torr, such as between 4 Torr and about 12 Torr, for example about 6 Torr or about 9 Torr, will deposit an n-type microcrystalline silicon layer having a crystalline fraction between about 20 percent and about 80 percent, for example between 50 percent and about 70 percent, at a rate of about 50 Å/min or more, such as about 150 Å/min or more.

In one embodiment, the n-type amorphous silicon layer 126 may be deposited by providing a gas mixture of hydrogen gas to silane gas in a ratio of about 20:1 or less, such as about 5:5:1 or 7.8:1. Silane gas may be provided at a flow rate between about 0.1 sccm/L and about 10 sccm/L, such as between about 1 sccm/L and about 10 sccm/L, between about 0.1 sccm/L and 5 sccm/L, or between about 0.5 sccm/L and about 3 sccm/L, for example about 1.42 sccm/L or 5.5 sccm/L. Hydrogen gas may be provided at a flow rate between about 1 sccm/L and about 40 sccm/L, such as between about 4 sccm/L and about 40 sccm/L, or between about 1 sccm/L and about 10 sccm/L, for example about 6.42 sccm/L or 27 sccm/L. Phosphine may be provided at a flow rate between about 0.0005 sccm/L and about 0.075 sccm/L, such as between about 0.0005 sccm/L and about 0.0015 sccm/L or between about 0.015 sccm/L and about 0.03 sccm/L, for example about 0.0095 sccm/L or 0.023 sccm/L. If phosphine is provided in a 0.5% molar or volume concentration in a carrier gas, then the dopant/carrier gas mixture may be provided at a flow rate between about 0.1 sccm/L and about 15 sccm/L, such as between about 0.1 sccm/L and about 3 sccm/L, between about 2 sccm/L and about 15 sccm/L, or between about 3 sccm/L and about 6 sccm/L, for example about 1.9 sccm/L or about 4.71 sccm/L. Applying RF power between about 25 mW/cm² and about 250 mW/cm², such as about 60 mW/cm² or about 80 mW/cm², at a chamber pressure between about 0.1 Torr and about 20 Torr, preferably between about 0.5 Torr and about 4 Torr, such as about 1.5 Torr, will deposit an n-type amorphous silicon layer at a rate of about 100 Å/min or more, such as about 200 Å/min or more, such as about 300 Å/min or about 600 Å/min.

It should be noted that in many embodiments pre-clean processes may be used to prepare substrates and/or reaction chambers for deposition of the above layers. A hydrogen or argon plasma pre-treat process may be performed to remove contaminants from substrates and/or chamber walls by supplying hydrogen gas or argon gas to the processing chamber between about 10 sccm/L and about 45 sccm/L, such as between about 15 sccm/L and about 40 sccm/L, for example about 20 sccm/L and about 36 sccm/L. In one example, the hydrogen gas may be supplied at about 21 sccm/L or the argon gas may be supplied at about 36 sccm/L. The treatment is accomplished by applying RF power between about 10 mW/cm² and about 250 mW/cm², such as between about 25 mW/cm² and about 250 mW/cm², for example about 60 mW/cm² or about 80 mW/cm² for hydrogen treatment and about 25 mW/cm² for argon treatment. In many embodiments it may be advantageous to perform an argon plasma pre-treatment process prior to depositing a p-type amorphous silicon layer, and a hydrogen plasma pre-treatment process prior to depositing other types of layers.

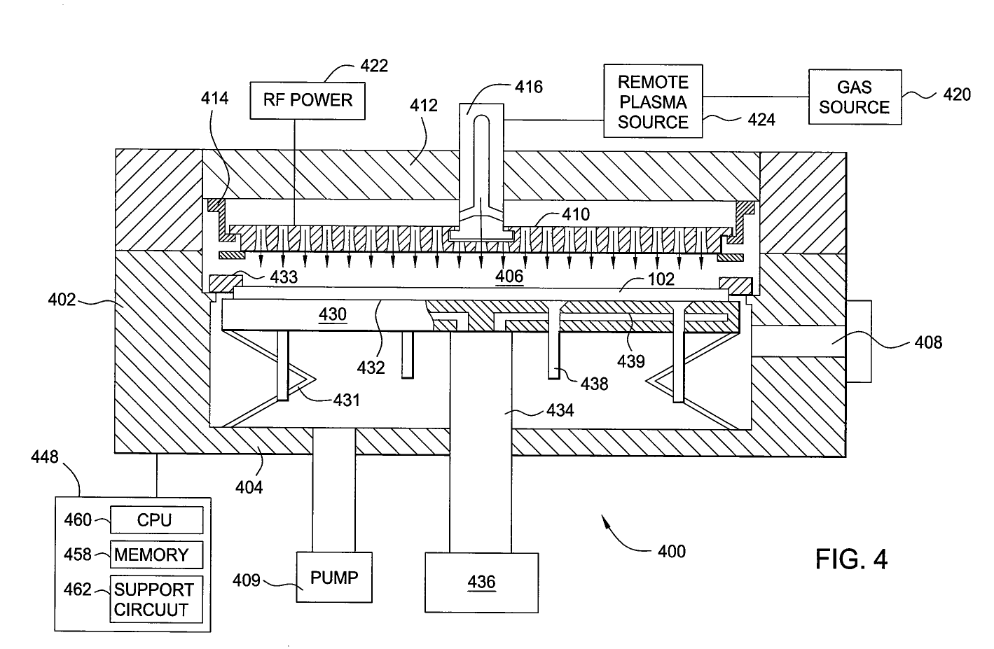

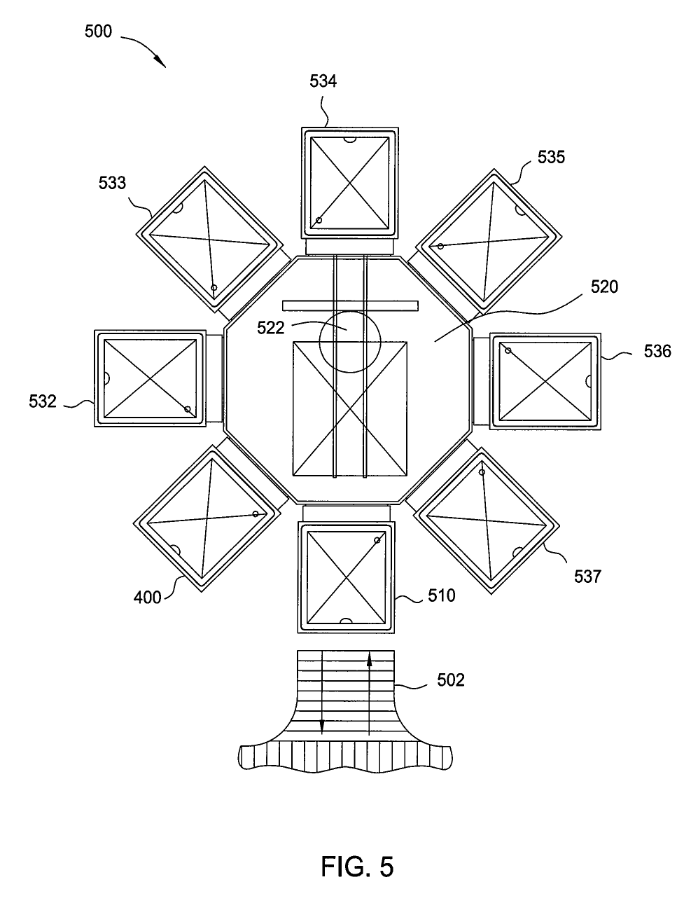

FIG. 3 depicts a process flow diagram for forming a portion of an amorphous based thin-film solar cell according to one embodiment of the invention. The process 300 starts at step 302 by providing a substrate, such as the substrate 102 into a processing chamber. The processing chamber may be any suitable deposition chamber, such as a chemical vapor deposition (CVD) chamber. One exemplary CVD chamber that may be utilized to form the amorphous based thin-film solar cell, such as the first junction cell 118 depicted in FIG. 1, is illustrated in FIG. 4, which will be further discussed below. In one embodiment, the substrate may be a thin sheet of metal, plastic, organic material, silicon, glass, quartz, polymer, or other suitable material. The substrate 102 may have a transparent conductive layer or a transparent conductive oxide (TCO) layer, such as the TCO layer 104 depicted in FIG. 1, formed thereon prior to transferring into the processing chamber.

At step 304, a p-type semiconductor layer, such as the p-type semiconductor layer 106 depicted in FIGS. 1 and 2, is formed on the substrate 102. The p-type semiconductor layer may be formed as a p-type microcrystalline silicon layer or a p-type amorphous silicon layer. In an exemplary embodiment depicted herein, the p-type semiconductor layer, such as the p-type semiconductor layer 106, is formed as a p-type amorphous silicon layer.

In one embodiment, the p-type amorphous silicon layer 106 may be deposited by providing a gas mixture of hydrogen gas to silane gas in a ratio of about 20:1 or less. Silane gas may be provided at a flow rate between about 1 sccm/L and about 10 sccm/L. Hydrogen gas may be provided at a flow rate between about 5 sccm/L and 60 sccm/L. Trimethylboron may be provided at a flow rate between about 0.005 sccm/L and about 0.05 sccm/L. If trimethylboron is provided in a 0.5% molar or volume concentration in a carrier gas, then the dopant/carrier gas mixture may be provided at a flow rate between about 1 sccm/L and about 10 sccm/L. Additionally, a carbon containing gas may be supplied in the gas mixture to deposit p-type amorphous silicon layer 106 as well to form p-type amorphous silicon layer 106 as a carbon doped p-type amorphous silicon layer. Suitable examples of carbon containing gas include CH₄, C₃H₈, C₄H₁₀, or C₂H₂, or any suitable carbon containing gas. Carbon containing gas may be provided at a flow rate between about 0.001 sccm/L and about 5 sccm/L. Applying RF power between about 15 mWatts/cm² and about 200 mWatts/cm² at a chamber pressure between about 0.1 Torr and 20 Torr, for example between about 1 Torr and about 4 Torr, will deposit a p-type amorphous silicon layer at about 100 Å/min or more. In one embodiment, the p-type amorphous silicon layer 106 may have a thickness between about 60 Å and about 300 Å.

At step 306, after the p-type amorphous silicon layer 106 is formed on the substrate 102, a barrier layer, such as the barrier layer 108 depicted in FIGS. 1 and 2, may be formed on the p-type amorphous silicon layer 106. It is noted that the barrier layer 108 may be formed within the same chamber in which the p-type amorphous silicon layer 106 is formed. It is noted that the barrier layer 108 may also be formed within the same chamber in which the subsequent intrinsic type semiconductor layer 110 is formed. Alternatively, the barrier layer 108 may be formed in any suitable deposition chamber, such as a separate stand-alone chamber, as needed.

In one embodiment, the barrier layer 108 is formed having a dopant, such as carbon, nitrogen, or other suitable elements, doped therein. In one embodiment, the barrier layer 108 is formed as a carbon containing silicon based layer. For example, the barrier layer 108 is formed as a carbon doped amorphous silicon layer, such as a silicon carbide layer (SiC). The barrier layer 108 serves as a cap layer and/or interface barrier layer that prevents the dopants, such as boron dopants, or other impurities from the underlying p-type amorphous silicon layer 106 from diffusing or penetrating into the nearby adjacent layers during the subsequent high temperature deposition process, thereby reducing the likelihood of contaminating or damaging the film layers and the solar cell devices formed on the substrate 102. It is believed that the carbon element formed in the barrier layer 108 can efficiently strengthen the silicon bonding microstructures with stronger silicon-carbon (Si—C) bonds formed therein, thereby providing a robust bonding network and thus preventing impurities and dopants from diffusion to the adjacent film layers. Boron diffusion is believed to be mediated by certain defects, such as dangling bonds formed in amorphous silicon, or interstitials in crystalline silicon layers. Accordingly, carbon element formed in the barrier layer 108 may act as trap sties to capture boron elements so as to slow down or eliminate the boron diffusion.

Furthermore, the barrier layer 108 is formed as a carbon rich film so as to be stable enough to against the thermal or plasma damage that may be generated during the subsequent manufacture process. The carbon rich barrier layer 108 also provides structural flexibility to offset minor structure changes from the underlying p-type layer 106 so that the addition of the barrier layer 108 in the solar cell structure can only produces negligible series resistance increase.

In one embodiment, the barrier layer 108 may be deposited by providing a gas mixture includes at least a carbon containing gas and a silicon containing gas. Suitable examples of carbon containing gas include CH₄, C₃H₈, C₄H₁₀, or C₂H₂, or any suitable carbon containing gas. Suitable examples of the silicon containing gas include silane (SiH₄), disilane (Si₂H₆), silicon tetrafluoride (SiF₄), silicon tetrachloride (SiCl₄), dichlorosilane (SiH₂Cl₂), combinations thereof and the like. In an exemplary embodiment, the carbon containing gas used to deposit the barrier layer 108 is CH₄ and the silicon containing gas used to deposit the barrier layer is SiH₄. The CH₄ gas supplied in the gas mixture has a ratio to silane gas of about 0.5:1 or less. Silane gas may be provided at a flow rate between about 1 sccm/L and about 10 sccm/L. The RF power is applied between about 15 mWatts/cm² and about 200 mWatts/cm² to the processing chamber. The chamber pressure is maintained between about 0.1 Torr and 20 Torr, such as between about 1 Torr and about 4 Torr. In one embodiment, the barrier layer 108 is formed to have a thickness between about 0 Å and about 200 Å, such as about 10 Å and about 25 Å, for example, about 20 Å.

In the embodiment wherein the barrier layer 108 and the p-type semiconductor layer 106 are formed in the same chamber, the gas mixture supplied during to the processing chamber for depositing may be varied to deposit different layers on the substrate during deposition stage. For example, in one embodiment, the gas mixture supplied to deposit the p-type semiconductor layer 106 may include at least a silicon containing gas, a carbon containing gas, and a Group III containing gas while the gas mixture supplied to deposit the barrier layer 108 may include at least a silicon containing gas, and a carbon containing gas. During deposition of the p-type semiconductor layer 106 and the barrier layer 108 in the same chamber, the gas mixture supplied to the processing chamber may initially include the silicon containing gas, Group III containing gas and the carbon containing gas. After the p-type semiconductor layer 106 has reached a desired thickness on the substrate 102, the Group III containing gas supplied in the gas mixture may subsequently turned off to deposit the barrier layer 108 on the substrate without breaking vacuum. The gas species supplied in the gas mixture may be smoothly switched and transitioned to deposit the p-type semiconductor layer 106 and the barrier layer 108 as needed so that the material layers can be deposited on the substrate 102 in a single chamber without transferring between different chambers. It is noted that the gas flow rate may be varied as need to deposit the p-type semiconductor layer 106

At step 308, after the barrier layer 108 is formed on the substrate, an intrinsic type semiconductor layer, such as the intrinsic type semiconductor layer 110 depicted in FIGS. 1-2, is formed on the barrier layer 108. The intrinsic type semiconductor layer may be formed as an intrinsic-type microcrystalline silicon layer or an intrinsic-type amorphous silicon layer. In an exemplary embodiment depicted herein, the intrinsic-type semiconductor layer, such as the intrinsic-type semiconductor layer 110, is formed as an intrinsic type amorphous silicon layer.

The intrinsic type amorphous silicon layer 110 is formed under a process condition having a relatively high temperature, a relatively low pressure, and a relatively low hydrogen dilution ratio (e.g., low H₂/SiH₄ ratio). The relatively high temperature, relatively low pressure, relatively low hydrogen dilution ratio (e.g., low H₂/SiH₄ ratio) process condition described herein results in an intrinsic type amorphous silicon layer 110 having relatively lower film bandgap that absorbs a broader light spectrum and improves conversion efficiency. It is believed that the relatively high temperature used during the deposition process may assist producing low bandgap films with low defect density and high current generation, which may advantageously improve the overall conversion efficiency of the solar cell junction. In one embodiment, the deposition temperature is controlled at a range greater than 200 degrees Celsius, such as between about 220 degrees Celsius and about 300 degrees Celsius, for example, between about 220 degrees Celsius and about 250 degrees Celsius. In certain circumstances, high temperature performed during the deposition process may adversely cause dopants in the p-type semiconductor layer 106 diffusing into the intrinsic type amorphous silicon layer 110 or adjacent film layers during deposition process. Accordingly, by adding the barrier layer 108, as described at step 306, disposed between the p-type semiconductor layer 106 and the intrinsic type amorphous silicon layer 110, the barrier layer 108 may efficiently suppress the likelihood of dopant diffusion to the intrinsic type amorphous silicon layer 110, thereby maintaining purity and desired properties of the intrinsic type amorphous silicon layer 110 during deposition process.

Furthermore, the relatively low deposition pressure, such as less than 2.5 Torr, may also assist depositing the intrinsic type amorphous silicon layer 110 with good optoelectronic and microstructural properties and in the mean while with less cluster phase hydrogen formed in the resultant film, leading to lower film bandgap. In one embodiment, the process pressure controlled during the deposition is less than about 2.5 Torr, such as about less than 2 Torr, such as about 0.1 Torr and about 1.8 Torr, for example, about 1 Torr and about 1.5 Torr. An RF power between about 15 milliWatts/cm² and about 250 milliWatts/cm² may be provided to the processing chamber.

Additionally, the relatively low hydrogen dilution supplied in the gas mixture for depositing the intrinsic type amorphous silicon layer 110 may also assist depositing the intrinsic type amorphous silicon layer 110 with low film bandgap. It is believed that lower hydrogen gas flow supplied in the gas mixture may reduce hydrogen content formed in the resultant film, thereby reducing the crystalline fraction formed in the resultant amorphous silicon layer 110. Low film bandgap may provide cluster phase hydrogen in amorphous silicon states of the amorphous silicon layer 110 and assist obtain light at a longer wavelength, thereby increasing current generation in the junction cells. In one embodiment, the hydrogen to silane ratio (H₂/SiH₄) supplied in the gas mixture is controlled between about less than 10, such as less than 6, for example between about 2 and about 5. Alternatively, silane gas supplied in the gas mixture may be controlled at a flow rate between about 1 sccm/L and about 10 sccm/L. Hydrogen gas may be controlled at a flow rate between about 2 sccm/L and 100 sccm/L. An optional carrier gas or inert gas, such as N₂, N₂O, NO₂, Ar, He or the like, may also be supplied into the gas mixture if necessary. In the embodiment wherein the carrier gas or inert gas is supplied into the processing chamber, the gas flow rate of the carrier gas or inert gas may be controlled at between about 2 sccm/L and about 100 sccm/L.

Accordingly, by utilizing the process conditions of relatively high deposition temperature, relatively low pressure and relatively low hydrogen dilution during the intrinsic type amorphous silicon deposition process, an amorphous silicon film with low film bandgap may be obtained. Furthermore, by adding the barrier layer 108 between the p-type semiconductor layer 106 and the intrinsic type amorphous silicon layer 110, the barrier layer 108 may efficiently prevent the dopants formed in the p-type semiconductor layer 106 or impurities from diffusing into the adjacent and/or upper intrinsic type amorphous silicon layer 110, thereby maintaining a desired purity and film properties of the intrinsic type amorphous silicon layer 110 formed in the junction cells. Therefore, the utilization of the relatively high temperature process performed in the intrinsic type amorphous silicon deposition process would not adversely damage or destroy the film properties or device performance of the solar cells, which is often found in the conventional practices. By combination of the particularly configured process conditions of intrinsic type amorphous silicon deposition process and the barrier layers formed in the junction cell, the amorphous silicon based solar cell junction can efficiently obtain and retain lights at longer wavelength after prolonged light-soaking, thereby improving the overall device performance and solar cell device conversion efficiency.

### System and Apparatus Configurations

FIG. 4 is a schematic cross-section view of one embodiment of a plasma enhanced chemical vapor deposition (PECVD) chamber 400 in which one or more films of a thin-film solar cell, such as the solar cells of FIGS. 1-2 may be deposited by the process described above, including the barrier layer 108 and the intrinsic type amorphous silicon layer 110. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 400 generally includes walls 402, a bottom 404, and a showerhead 410, and substrate support 430 which define a process volume 406. The process volume 406 is accessed through a valve 408 such that the substrate may be transferred in and out of the chamber 400. The substrate support 430 includes a substrate receiving surface 432 for supporting a substrate and stem 434 coupled to a lift system 436 to raise and lower the substrate support 430. A shadow ring 433 may be optionally placed over periphery of the substrate 102. Lift pins 438 are moveably disposed through the substrate support 430 to move a substrate to and from the substrate receiving surface 432. The substrate support 430 may also include heating and/or cooling elements 439 to maintain the substrate support 430 at a desired temperature. The substrate support 430 may also include grounding straps 431 to provide RF grounding at the periphery of the substrate support 430.

The showerhead 410 is coupled to a backing plate 412 at its periphery by a suspension 414. The showerhead 410 may also be coupled to the backing plate by one or more center supports 416 to help prevent sag and/or control the straightness/curvature of the showerhead 410. A gas source 420 is coupled to the backing plate 412 to provide gas through the backing plate 412 and through the showerhead 410 to the substrate receiving surface 432. A vacuum pump 409 is coupled to the chamber 400 to control the process volume 406 at a desired pressure. An RF power source 422 is coupled to the backing plate 412 and/or to the showerhead 410 to provide a RF power to the showerhead 410 so that an electric field is created between the showerhead and the substrate support 430 to generate plasma from the gases between the showerhead 410 and the substrate support 430. Various RF frequencies may be used, such as a frequency between about 0.3 MHz and about 200 MHz. In one embodiment the RF power source is provided at a frequency of 13.56 MHz.

A remote plasma source 424, such as an inductively coupled remote plasma source, may also be coupled between the gas source and the backing plate. Between processing substrates, a cleaning gas may be provided to the remote plasma source 424 so that a remote plasma is generated and provided to clean chamber components. The cleaning gas may be further excited by the RF power source 422 provided to the showerhead. Suitable cleaning gases include but are not limited to NF₃, F₂, and SF₆.

The deposition methods for one or more layers, such as one or more of the layers of FIGS. 1-2, may include the following deposition parameters in the process chamber of FIG. 4 or other suitable chamber. A substrate having a surface area of 10,000 cm² or more, for example about 40,000 cm² or more, such as 55,000 cm² or more is provided to the chamber. It is understood that after processing the substrate may be cut to form smaller solar cells.

In one embodiment, the heating and/or cooling elements 439 may be set to provide a substrate support temperature during deposition of about 400° C. or less, preferably between about 100° C. and about 400° C., such as between about 150° C. and about 300° C., for example about 200° C.

The spacing during deposition between the top surface of a substrate disposed on the substrate receiving surface 432 and the showerhead 410 may be between 400 mil and about 1,200 mil, for example between 400 mil and about 800 mil.

A controller 448 is coupled to the processing chamber 400. The controller 448 includes a central processing unit (CPU) 460, a memory 458, and support circuits 462. The controller 448 is utilized to control the process sequence, regulating the gas flows from the gas source 420 into the chamber 400 and controlling power supply from the RF power source 422 and the remote plasma source 424. The CPU 460 may be of any form of a general purpose computer processor that can be used in an industrial setting. The software routines can be stored in the memory 458, such as random access memory, read only memory, floppy or hard disk drive, or other form of digital storage. The support circuits 462 are conventionally coupled to the CPU 460 and may comprise cache, clock circuits, input/output subsystems, power supplies, and the like. The software routines, when executed by the CPU 460, transform the CPU into a specific purpose computer (controller) 448 that controls the processing chamber 400 such that the processes are performed in accordance with the present invention. The software routines may also be stored and/or executed by a second controller (not shown) that is located remotely from the processing chamber 400.

FIG. 5 is a top schematic view of one embodiment of a process system 500 having a plurality of process chambers 400, 532-537, such as PECVD chamber 400 of FIG. 4 or other suitable chambers capable of depositing silicon films. The process system 500 includes a transfer chamber 520 coupled to a load lock chamber 510 and the process chambers 400, 532-537. The load lock chamber 510 allows substrates to be transferred between the ambient environment outside the system and vacuum environment within the transfer chamber 520 and process chambers 400, 532-537. The load lock chamber 510 includes one or more evacuatable regions holding one or more substrate. The evacuatable regions are pumped down during input of substrates into the system 500 and are vented during output of the substrates from the system 500. The transfer chamber 520 has at least one vacuum robot 522 disposed therein that is adapted to transfer substrates between the load lock chamber 510 and the process chambers 400, 532-537. While seven process chambers are shown in FIG. 5; this configuration is not intended to be limiting as to the scope of the invention, since the system may have any suitable number of process chambers.

In certain embodiments of the invention, the system 500 is configured to deposit the first p-i-n junction (e.g., reference numeral 118) of a single or a multi-junction solar cell. In one embodiment, one of the process chambers 400, 532-537 is configured to deposit the p-type layer(s) 106 and barrier layer 108 of the first p-i-n junction 118 while the remaining process chambers 400, 532-537 are each configured to deposit both the intrinsic type layer(s) 110 and the n-type layer(s) 112. The intrinsic type layer(s) 110 and the n-type layer(s) 112 of the first p-i-n junction 118 may be deposited in the same chamber without any passivation process in between the deposition steps. Thus, in one configuration, a substrate enters the system through the load lock chamber 510, the substrate is then transferred by the vacuum robot into the dedicated process chamber configured to deposit the p-type layer(s). Next, after forming the p-type layer 106, the substrate is transferred by the vacuum robot into one of the remaining process chamber configured to deposit both the intrinsic type layer(s) 110 and the n-type layer(s) 112. After forming the intrinsic type layer(s) 110 and the n-type layer(s) 112, the substrate is transferred by the vacuum robot 522 back to the load lock chamber 510. In certain embodiments, the time to process a substrate with the process chamber to form the p-type layer(s) 106 and the barrier layer 108 is approximately 4 or more times faster, for example about 6 or more times faster, than the time to form the intrinsic type layer(s) 110, and the n-type layer(s) 112 in a single chamber. Therefore, in certain embodiments of the system to deposit the first p-i-n junction 118, the ratio of p-chambers to i/n-chambers is 1:4 or more, such as about 1:6 or more. The throughput of the system 500 including the time to provide plasma cleaning of the process chambers may be about 10 substrates/hr or more, such as about 20 substrates/hr or more.

In certain embodiments of the invention, a system 500 is configured to deposit the second p-i-n junction (e.g., reference numeral 128) of a multi-junction solar cell. In one embodiment, one of the process chambers 400, 532-537 is configured to deposit the p-type layer(s) 122 of the second p-i-n junction 128 while the remaining process chambers 400, 532-537 are each configured to deposit both the intrinsic type layer(s) 124 and the n-type layer(s) 126. The intrinsic type layer(s) 124 and the n-type layer(s) 126 of the second p-i-n junction 128 may be deposited in the same chamber without any passivation process in between the deposition steps. In certain embodiments, the time to process a substrate with the process chamber to form the p-type layer(s) 122 is approximately 4 or more times faster than the time to form the intrinsic type layer(s) 124 and the n-type layer(s) 126 in a single chamber. Therefore, in certain embodiments of the system to deposit the second p-i-n junction 128, the ratio of p-chambers to i/n-chambers is 1:4 or more, such as about 1:6 or more. The throughput of the system including the time to provide plasma cleaning of the process chambers may be about 3 substrates/hr or more, for example about 5 substrates/hr or more.

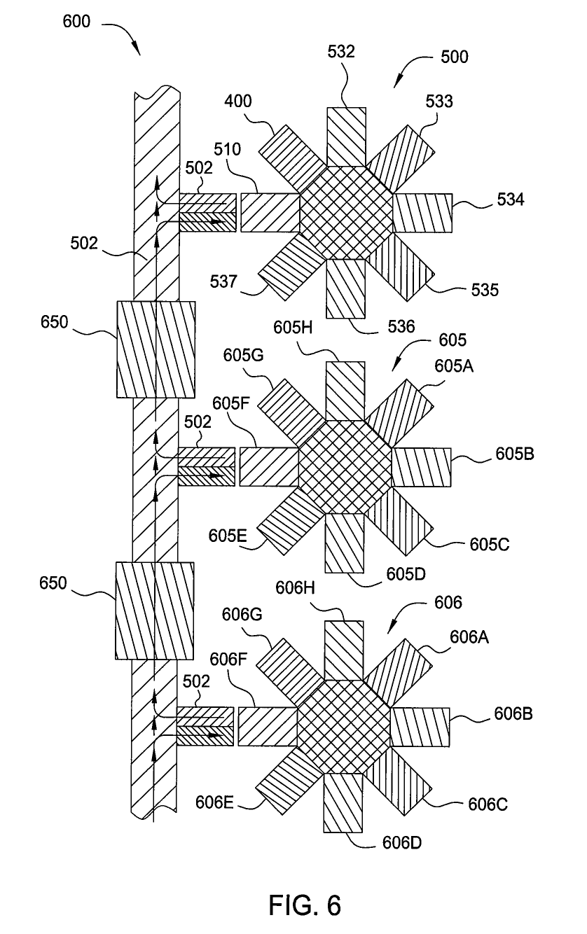

FIG. 6 illustrates one configuration of a portion of a production line 900 that has a plurality of deposition systems 500, 605, 606, or cluster tools, that are transferrably connected by automation devices 602. In one configuration, as shown in FIG. 6, the production line 600 comprises a plurality of deposition systems 500, 605, 606 that may be utilized to form one or more layers, form p-i-n junction(s), or form a complete solar cell device on a substrate 102. The systems 500, 605, 606 may be similar to the system 500 depicted in FIG. 5, but are generally configured to deposit different layer(s) or junction(s) on the substrate 102. In general, each of the deposition systems 500, 905, 906 each have a load lock chamber 510, 605F, 606F that are each in transferrable communication with an automation device 602.

During process sequencing, a substrate is generally transported from a system automation device 602 to one of the systems 500, 605, 606. In one embodiment, the system 606 has a plurality of chambers 606A-606H that are each configured to deposit or process one or more layers in the formation of a first p-i-n junction, the system 605 having a plurality of chambers 605A-605H is configure to deposit or process one or more layers in the formation of a second p-i-n junction. It is noted that the number of systems and the number of the chambers configured to deposit each layer in each of the systems may be varied to meet different process requirements and configurations.

The automation device 502 may generally comprise a robotic device or conveyor that is adapted to move and position a substrate. In one example, the automation device 502 is a series of conventional substrate conveyors (e.g., roller type conveyor) and/or robotic devices (e.g., 6-axis robot, SCARA robot) that are configured to move and position the substrate within the production line 600 as desired. In one embodiment, one or more of the automation devices 502 also contains one or more substrate lifting components, or drawbridge conveyors, that are used to allow substrates upstream of a desired system to be delivered past a substrate that would be blocking its movement to another desired position within the production line 600. In this way the movement of substrates to the various systems will not be impeded by other substrates waiting to be delivered to another system.

In one embodiment of the production line 600, a patterning chamber 650 is in communication with one or more of the automation device 502, and is configured to perform a patterning process on one or more of the layers formed in the junction cells 118, 128. It is also contemplated that the patterning process can also be used to etch one or more regions in one or more of the previously formed layers during the solar cell devices formation process as needed. While the configurations of the patterning chamber 650 generally discuss etching type patterning processes, this configuration need not be limiting as to the scope of the invention described herein. In one embodiment, the patterning chamber 650 is used to remove one or more regions in one or more of the formed layers and/or deposit one or more material layers (e.g., dopant containing materials, metal paste) on the one or more of the formed layers on the substrate surface.

While the foregoing is directed to embodiments of the present invention, other and further embodiments of the invention may be devised without departing from the basic scope thereof, and the scope thereof is determined by the claims that follow. For example, the process chamber of FIG. 4 has been shown in a horizontal position. It is understood that in other embodiments of the invention the process chamber may be in any non-horizontal position, such as vertical. Embodiments of the invention have been described in reference to the multi-process chamber cluster tool in FIGS. 5 and 6, but in-line systems and hybrid in-line/cluster systems may also be used. Embodiments of the invention have been described in reference to a first system configured to form a first p-i-n junction and a second system to form a second p-i-n junction, but the first p-i-n junction and a second p-i-n junction may also be formed in a single system. Embodiments of the invention have been described in reference to a process chamber adapted to deposit an intrinsic type layer and a n-type layer, but separate chambers may be adapted to deposit the intrinsic type layer and the n-type layer and a single process chamber may be adapted to deposit both a p-type layer, a barrier layer and an intrinsic type layer. Finally, the embodiments described herein are p-i-n configurations generally applicable to transparent substrates, such as glass, but other embodiments are contemplated in which n-i-p junctions, single or multiply stacked, are constructed on opaque substrates such as stainless steel or polymer in a reverse deposition sequence.

Thus, an apparatus and methods for forming an intrinsic amorphous silicon layer and a barrier layer in a solar cell device are provided. The method advantageously produces an amorphous silicon layer used in a solar cell junction with low film optical bandgap and broad wavelength absorption range along with a barrier layer that can generate high current, thereby increasing the photoelectric conversion efficiency and device performance of the PV solar cell as compared to conventional methods.

While the foregoing is directed to embodiments of the present invention, other and further embodiments of the invention may be devised without departing from the basic scope thereof, and the scope thereof is determined by the claims that follow.

What is claimed is:

1. A photovoltaic device, comprising:
a p-type amorphous silicon layer formed on a substrate;
a barrier layer formed on the p-type amorphous silicon layer, wherein the barrier layer is a carbon doped amorphous silicon layer; and
an intrinsic type amorphous silicon layer formed on the barrier layer.

2. The photovoltaic device of claim 1, further comprising:
an n-type microcrystalline silicon layer formed over the intrinsic type amorphous silicon layer.

3. The photovoltaic device of claim 1, wherein the barrier layer has a thickness between about 0 Å and about 200 Å.

4. The photovoltaic device of claim 1, wherein the p-type amorphous silicon layer is a boron doped silicon carbide layer.

5. A method of forming a solar cell device, comprising:
forming a p-type amorphous silicon layer on a surface of a substrate;
forming a barrier layer on the p-type amorphous silicon layer, wherein the barrier layer is a carbon doped amorphous silicon layer; and
forming an intrinsic type amorphous silicon layer on the barrier layer.

6. The method of claim 5, wherein forming the intrinsic type amorphous silicon layer further comprises:
providing a gas mixture to the surface of the substrate in a processing chamber, wherein the gas mixture includes a ratio of a hydrogen gas to a silane gas less than 6;
controlling a substrate temperature between about 220 degrees Celsius and about 250 degrees Celsius; and
controlling a process pressure in the processing chamber at between about 1 Torr and about 2 Torr.

7. The method of claim 6, wherein the ratio of the hydrogen gas to silane gas supplied in the gas mixture is controlled at between about 2 and about 5.

8. The method of claim 5, wherein the barrier layer has a thickness between about 0 Å and about 200 Å.

9. The method of claim 5, wherein forming the barrier layer further comprises:
supplying a gas mixture to the surface of the substrate, wherein the gas mixture includes at least a carbon containing gas and a silicon containing gas.

10. The method of claim 9, wherein the carbon containing gas is CH₄ and the silicon containing gas is SiH₄.

11. The method of claim 9, wherein the p-type amorphous silicon layer and the barrier layer are formed in a single processing chamber.

12. The method of claim 9, wherein the barrier layer and the intrinsic type amorphous silicon layer are formed in a single processing chamber.

13. The method of claim 5, wherein the p-type amorphous silicon layer is a boron doped silicon carbide layer.

14. A method of forming a solar cell device, comprising:
supplying a first gas mixture in a processing chamber to form a p-type amorphous silicon layer on a surface of a substrate;
supplying a second gas mixture in the processing chamber to form a barrier layer on the p-type amorphous silicon layer, wherein the barrier layer is a carbon doped amorphous silicon layer and the second gas mixture supplied to form the barrier layer includes at least a carbon containing gas and a silicon containing gas; and
forming an intrinsic type amorphous silicon layer on the barrier layer.

15. The method of claim 14, wherein forming the intrinsic type amorphous silicon layer further comprises:
providing a third gas mixture to the surface of the substrate in a processing chamber, wherein the third gas mixture includes a ratio of a hydrogen gas to a silane gas less than 6;
controlling a substrate temperature between about 220 degrees Celsius and about 250 degrees Celsius; and
controlling a process pressure in the processing chamber at between about 1 Torr and about 2 Torr.

16. The method of claim 14, wherein the first gas mixture includes at least a Group III containing gas, a carbon containing gas and a silicon containing gas, wherein the first gas mixture is transitioned to the second gas mixture by stopping the flow of the Group III containing gas supplied in the first gas mixture.

17. The method of claim 14, wherein the carbon containing gas is CH₄ and the silicon containing gas is SiH₄.

18. The method of claim 14, wherein the barrier layer has a thickness between about 0 Å and about 200 Å.

19. The method of claim 14, wherein the p-type amorphous silicon layer and the barrier layer are formed in a single processing chamber.

20. The method of claim 14, wherein the barrier layer and the intrinsic type amorphous silicon layer are formed in a single processing chamber.
